(19) United States
(12) Patent Application Publication
(10) Pub. No.: US 2009/0218219 A1
(43) Pub. Date: Sep. 3, 2009

(54) Manufacturing Apparatus

(75) Inventor: Shunpei Yamazaki, Tokyo (JP)

Correspondence Address: COOK ALEX LTD, SUITE 2850, 200 WEST ADAMS STREET, CHICAGO, IL, 60606, US

(73) Assignee: Semiconductor Energy Laboratory Co., Ltd.

(21) Appl. No.: 12/391,895

(22) Filed: Feb. 24, 2009

(30) Foreign Application Priority Data
Feb. 29, 2008 (JP) 2008-049691

(51) Int. Cl. C23C 14/34; C23C 16/44

(52) U.S. Cl. 204/298.25; 118/719; 118/620

(57) ABSTRACT

A manufacturing apparatus in which an organic thin film such as a light emitting layer is formed with high material use efficiency or high operating efficiency and a light emitting device is manufactured, is provided. The manufacturing apparatus includes a load chamber, a common chamber connected to the load chamber, a plurality of treatment chambers connected to the common chamber, and a laser light source, in which deposition is selectively performed on a first substrate by forming a material layer on a second substrate in the treatment chamber in advance; aligning the second substrate and the first substrate in the common chamber; and then scanning the second substrate with laser light. In the manufacturing apparatus, selective deposition is performed on the first substrate more than once in the common chamber.

### BACKGROUND OF THE INVENTION

1. Field of the Invention

The present invention relates to a manufacturing apparatus equipped with a deposition apparatus used for deposition of a material which can be deposited by evaporation (hereinafter the material is referred to as an evaporation material); a light emitting device in which a layer containing an organic compound that is formed using the manufacturing apparatus serves as a light emitting layer; and a method for manufacturing the same. Specifically, the present invention relates to a manufacturing apparatus for depositing a stack of layers.

2. Description of the Related Art

In recent years, a light emitting device having an EL element as a self-luminous element has been actively researched. This light emitting device is also called an organic EL display or an organic light emitting diode. Such a light emitting device has characteristics of high response speed which is suitable for displaying moving images, low-voltage, low-power-consumption drive, and the like; therefore, the light emitting device has attracted great attention as a next-generation display such as a new-generation mobile phone or personal digital assistant (PDA).

An EL element having a layer containing an organic compound as a light emitting layer has a structure in which the layer containing an organic compound (hereinafter referred to as an EL layer) is interposed between an anode and a cathode. By applying an electric field to the anode and the cathode, luminescence (electroluminescence) is generated from the EL layer. Light emitted from the EL element includes light emission (fluorescence) which is generated in returning from a singlet excited state to a ground state and light emission (phosphorescence) which is generated in returning from a triplet excited state to a ground state.

The above-mentioned EL layer has a stacked-layer structure typified by a hole transporting layer, a light emitting layer, and an electron transporting layer. Further, EL materials for forming EL layers are roughly classified into low molecular (monomer) materials and high molecular (polymer) materials. A low molecular material is deposited using an evaporation apparatus.

In a conventional evaporation apparatus, a substrate is set in a substrate holder; and a crucible which contains an EL material, that is, an evaporation material, a shutter for preventing the rise of the EL material to be sublimated, and a heater for heating the EL material in the crucible are included. Then, the EL material heated by the heater sublimates to form a film on the rotating substrate. At this time, the distance between the substrate and the crucible needs to be greater than or equal to 1 m, for example, in order to perform uniform deposition on a large area substrate.

Furthermore, the conventional evaporation apparatus requires some distance between a substrate and an evaporation source in order to obtain a uniform film. Therefore, the evaporation apparatus itself gets larger, and time it takes to exhaust air from each deposition chamber in the evaporation apparatus is increased. In addition, since a substrate is rotated in the evaporation apparatus, there are limits on the evaporation apparatus for processing a large-area substrate.

Accordingly, evaporation apparatuses (Reference 1: Japanese Published Patent Application No. 2001-247959, and Reference 2: Japanese Published Patent Application No. 2002-60926) have been proposed.

In addition, a manufacturing apparatus has been proposed in which a plurality of treatment chambers is provided for a common chamber; a substrate is sequentially moved from a treatment chamber to another treatment chamber; and processing is performed plural times, (Reference 3, Japanese Published Patent Application No. 2001-102170).

### SUMMARY OF THE INVENTION

In the present invention, when a full-color flat panel display is manufactured using organic EL elements which emit red light, green light, and blue light respectively, positional accuracy of selective deposition is not very high and thus the distance between pixels having different emission colors is designed to be wide. The present invention is to provide a manufacturing apparatus equipped with a deposition apparatus in which high positional accuracy of selective deposition can be obtained and the distance between pixels having different emission colors can be designed to be short.

The present invention provides a manufacturing apparatus in which an organic thin film such as a light emitting layer is formed with high material use efficiency or high operating efficiency over a large-area substrate having a size of, for example, 320 mm×400 mm, 370 mm×470 mm, 550 mm×650 mm, 600 mm×720 mm, 680 mm×880 mm, 1000 mm×1200 mm, 1100 mm×1250 mm, or 1150 mm×1300 mm and a light emitting device is manufactured.

A conventional manufacturing apparatus is provided with a plurality of treatment chambers connected to a common chamber, and processing is performed plural times by sequentially transferring a deposition target substrate from a treatment chamber to another treatment chamber through the common chamber. In the case of manufacturing a full-color flat panel display, for example, after selectively forming a red light emitting layer in a first deposition chamber, a deposition target substrate is transferred to a second deposition chamber through the common chamber; after selectively forming a blue light emitting layer in the second deposition chamber, the deposition target substrate is transferred to a third deposition chamber through the common chamber; then, a green light emitting layer is selectively formed in the third treatment chamber. In this case, the deposition target substrate is transferred from the common chamber at least three times. Further, one deposition chamber is provided with at least an evaporation source, a film thickness monitor, an alignment mechanism which aligns an evaporation mask and a substrate, a substrate rotating mechanism, and the like. Furthermore, in the conventional manufacturing apparatus, the time it takes to have a constant evaporation rate is long; evaporation is continued in each deposition chamber; and evaporation is continued also in a deposition chamber where deposition is not being performed. Besides, evaporation is continued not only while deposition is being performed on a substrate but also while a substrate is being transferred to a deposition chamber, while alignment is being performed, or while a substrate is being transferred from a deposition chamber. Therefore, it cannot be said that high material use efficiency or high operating efficiency is obtained in the conventional manufacturing apparatus. Note that it is said that the material use efficiency of a conventional manufacturing apparatus using resistance heating is less than 5%.

In the present manufacturing apparatus, after a deposition target substrate is transferred to a common chamber, deposition of a stack of layers is completed in the common chamber, and then the deposition target substrate is transferred from the common chamber at least a time. A substrate having a material layer is prepared in a treatment chamber connected to the common chamber; the substrate having a material layer is transferred to the common chamber; the substrate having a material layer and the deposition target substrate are aligned in the common chamber; the pair of substrates are overlapped with each other to be fixed; and laser light irradiation is performed from a window provided for the common chamber to perform deposition selectively on the deposition target substrate.

That is, it is not a deposition target substrate (a first substrate), but a substrate which is provided with a material layer in advance that is transferred to the common chamber to perform deposition. In the case of manufacturing a full color flat panel display, for example, a deposition target substrate is disposed to overlap with a second substrate having a red light emitting layer in the common chamber to which the substrates are transferred, and a red light emitting layer is selectively formed by laser light irradiation. A light absorbing layer is selectively provided on the second substrate; a material layer having a red light emitting material is provided thereon; the light absorbing layer is irradiated with laser light which has passed through the second substrate; and by heating the material layer indirectly, deposition is performed on the facing deposition target substrate surface. Subsequently, the deposition target substrate is disposed to overlap with a third substrate having a blue light emitting layer in the common chamber, and a blue light emitting layer is selectively formed by laser light irradiation. Then, the deposition target substrate is disposed to overlap with a fourth substrate having a green light emitting layer in the common chamber, and a green light emitting layer is selectively formed by laser light irradiation. The second substrate, the third substrate, and the fourth substrate are subjected to deposition in their respective treatment chambers connected to the common chamber, sequentially transferred to the common chamber and aligned with the deposition target substrate. If a plurality of second substrates on which a material layer is formed is prepared in advance, deposition can be performed with preferable work efficiency.

Furthermore, the present invention is not limited to the manufacturing apparatus which sequentially transfers substrates, and the manufacturing apparatus may have a mechanism in which the second substrate, the third substrate, and the fourth substrate are transferred to the common chamber almost simultaneously. In that case, the third substrate and the fourth substrate are kept in the common chamber while deposition is being performed using the second substrate, and the second substrate on which the deposition has been performed is replaced with the third substrate; thus, alignment with a deposition target substrate can be performed with preferable work efficiency. In addition, if the manufacturing apparatus has a mechanism in which the first substrate that is the deposition target substrate can be transferred to the common chamber almost simultaneously in addition to the second substrate, the third substrate, and the fourth substrate, the degree of vacuum in the common chamber can be kept. The transference of a substrate includes at least a series of operations in which the degrees of vacuum in two treatment chambers having a gate valve therebetween are adjusted to be about the same; the gate valve is opened; the substrate is transferred by a transfer robot; then, the gate valve is closed. Therefore, standby time of the deposition target substrate can be decreased by opening a plurality of gate valves and transferring the plurality of substrates to the common chamber almost simultaneously. Furthermore, when deposition of a stack of layers is performed in the common chamber, the period of time from the end of deposition to the start of the next deposition on the deposition target substrate can be shortened, and impurities on a surface of a film which is exposed between the end of the deposition to the start of the next deposition can be reduced.

In a conventional multi-chamber manufacturing apparatus, a common chamber is used for transferring a substrate; however, in the present invention, a material layer is deposited on a deposition target substrate, for example, a substrate provided with a thin film transistor in the common chamber. Furthermore, work efficiency can be improved by performing deposition of a stack of layers in the common chamber.

It is difficult for a conventional evaporation apparatus (an evaporation apparatus using resistance heating) to prevent a material vaporized from an evaporation source from adhering to an inner wall of a chamber or a component provided inside the chamber. In case where the material vaporized from the evaporation source adheres to the inner wall of the chamber or the component provided inside the chamber, there is a possibility that the material is diffused again in the chamber for some reasons and adheres to the deposition target substrate unintentionally. In particular, in the case where a full color flat panel display is manufactured using the conventional evaporation apparatus, a red light emitting layer, a blue light emitting layer, and a green light emitting layer are sequentially formed in different deposition chambers, and different evaporation masks are used. The different evaporation masks are used for preventing color mixing of light emitting materials when material layers having different emission colors are evaporated.

In the conventional evaporation apparatus, when deposition is performed selectively, an evaporation mask having an opening portion is placed between a deposition target substrate and an evaporation source. Therefore, an alignment means is provided for each deposition chamber, and the evaporation mask and the deposition target substrate are aligned with each other. Further, there are limitations on the size of the opening of the conventional evaporation mask in terms of processing technique, and furthermore, it is difficult to align a substrate and an evaporation mask having a large area without bending. When the evaporation mask bends, a problem that deposition is performed on a larger region than that of the opening of the evaporation mask becomes significant.

Further, in the conventional evaporation apparatus, larger quantity of materials is necessary than what is deposited on the deposition target substrate because evaporation is performed until the evaporation rate becomes constant using a film thickness monitor, and deposition is performed on the deposition target substrate after the evaporation rate becomes constant. That is, time for the evaporation rate to become constant is long. Moreover, a crucible for storing a material by resistance heating is formed of a ceramic material such as alumina, which is hard to heat and hard to cool after being heated to high temperatures once.

In the conventional evaporation apparatus, a shutter for preventing unintended evaporation from an evaporation source is provided in a deposition chamber, and the unintended evaporation is prevented by closing the shutter. However, because the distance between the shutter and the crucible is short, the space between the shutter and the crucible is filled with a deposition when evaporation is performed with the shutter closed, and the shutter adheres to the crucible, so that there is a possibility that the shutter can not open. Thus, the shutter is provided with the interval between the shutter and the crucible opened to some extent, and scattering of a small amount of a material from a gap into the chamber has been overlooked.

In the present invention, a film thickness monitor for a constant evaporation rate is not provided, and a substrate on which a material layer is formed in advance and a deposition target substrate are irradiated with laser light with a short distance between the substrates; thus, deposition on an inner wall of the chamber or a component provided inside the chamber can be reduced. In addition, by switching on/off the laser, the start and the stop of the deposition can be controlled. Further, after the laser irradiation, the material layer overlapping with a region irradiated with laser light disappears, and deposition is performed on the deposition target substrate with little loss.

Further, after the substrate provided with a material layer is used for the deposition in the common chamber, the substrate on which the deposition has completed is changed for a different substrate provided with a material layer, and alignment with the deposition target substrate is performed to perform deposition of a stack of layers. Therefore, positional accuracy of selective deposition can be enhanced because the same alignment means provided for the common chamber is used. Further, the total number of components of alignment means included in the manufacturing apparatus can be reduced.

The positional accuracy of deposition is a big problem in miniaturizing the pitch of display pixels, which accompanies increase in the definition (increase in the number of pixels) of a light emitting device and reduction in size of the light emitting device. Thus, when deposition is performed selectively, it is effective to improve the positional accuracy of deposition using the same alignment means.

An aspect of the present invention disclosed in this specification is a manufacturing apparatus including a load chamber, a common chamber connected to the load chamber, a plurality of treatment chambers connected to the common chamber, and a laser light source, wherein a chamber wall of the common chamber has a window, in a lower part thereof, through which laser light from the laser light source passes, and the common chamber has a vacuum exhaust means, an alignment means for substrates, and a transfer means for transferring substrates from the plurality of treatment chambers.

The scanning of the laser light is performed by moving the substrate which overlaps with the laser light above the window relatively to laser light so as to move an irradiation region of a laser beam with which the substrate is irradiated through the window. It can be said that the total time it takes to align substrates and scan laser light is deposition time.

The present invention solves at least one of the above-mentioned problems.

A first substrate on which at least an electrode and a thin film transistor are formed, and a second substrate on which a material layer is formed are aligned with each other, and the second substrate is irradiated with laser light to heat the material layer, thereby performing deposition on the first substrate. Therefore, an alignment means aligns the substrates so that a surface of the second substrate on which the material layer is formed faces a deposition target surface of the first substrate, and fixes the distance between the substrates. Another aspect of the present invention includes a manufacturing apparatus having a load chamber, a common chamber connected to the load chamber, a plurality of treatment chambers connected to the common chamber, and a laser light source, wherein a chamber wall of the common chamber has a window, in a lower part thereof, through which laser light from the laser light source passes; the common chamber has a vacuum exhaust means, an alignment means for a first substrate and a second substrate, and a substrate moving means for moving the first substrate and the second substrate in a parallel or perpendicular direction to one side the window in a state of fixing both the substrates; one of the plurality of treatment chambers has a means for forming a material layer on the second substrate; and the alignment mean aligns the substrates so that a surface of the second substrate on which the material layer is formed faces a deposition target surface of the first substrate, and fixes the distance between the substrates.

In the above structure, the common chamber has a transfer means for transferring the second substrate on which the material layer is formed from the treatment chamber. The transfer means is a transfer robot or a transfer roller. When the deposition on the second substrate in the treatment chamber is performed with the deposition surface upward (for example, a spin coating method), that is, with a face-up system, the second substrate is transferred into the chamber by the transfer means provided for the common chamber and aligned with the first substrate, whose electrode forming surface is made to face downward. When the deposition on the second substrate in the treatment chamber is performed with the deposition surface downward, that is, with a face-down system, after the second substrate is transferred into the chamber by the transfer means provided for the common chamber, the substrate surface is inverted and the second substrate is aligned with the first substrate, whose electrode forming surface is made to face downward. Note that a mechanism for inverting the substrate surface can be provided for the transfer robot.

Note that in the above structure, the window is rectangular or square; however, it may be circular or elliptical. A material which transmits light, such as quartz, may be used for the window, and the window may function as an optical system for laser light which is introduced into the chamber. Further, a shutter is preferably provided in the chamber so as to prevent the deposition target substrate from being irradiated with laser light by an operation error and to prevent dust from adhering to the deposition target substrate. In the case where a shutter is provided, for example, the shutter is opened at the start of deposition; laser light is introduced into the chamber; and the shutter is closed at the end of the deposition. In the case where the window provided for a lower part of the chamber wall is circular or elliptical, the substrate moving means has a structure in which the substrate is moved in a parallel or perpendicular direction to a diameter or a long axis of the window. The substrate moving means provided in the common chamber is a moving means which can move at a maximum speed of 1 m/sec, and is a moving means which utilizes a transfer robot or a ball screw.

The present invention solves at least one of the above-mentioned problems.

Further, in the above structure, as the laser light source, one or more of the following lasers can be used: a gas laser such as an Ar laser, a Kr laser, or an excimer laser; and a solid-state laser such as a laser whose medium is single-crystal YAG, YVO₄, forsterite (Mg₂SiO₄), YAlO₃, or GdVO₄ to which one or more of Nd, Yb, Cr, Ti, Ho, Er, Tm, and Ta has been added as a dopant, a polycrystalline (ceramic) YAQ Y₂O₃, YVO₄, YAlO₃, or GdVO₄ to which one or more of Nd, Yb, Cr, Ti, Ho, Er, Tm, and Ta has been added as a dopant, a glass laser, a ruby laser, an alexandrite laser, a Ti:sapphire laser, or a fiber laser. Alternatively, a second harmonic or a third harmonic oscillated from the above-described solid-state laser, or further, other higher harmonics can be used. Note that, when a solid-state laser whose laser medium is solid is used, there are advantages in that a maintenance-free condition can be maintained for a long time and output is relatively stable.

Further, because the laser light has a repetition rate of greater than or equal to 10 MHz and a pulse width of greater than or equal to 100 fs and less than or equal to 10 ns, laser irradiation can be performed in a short time; therefore, thermal diffusion can be controlled and a minute pattern can be formed. Furthermore, the laser light having a repetition rate of greater than or equal to 10 MHz and a pulse width of greater than or equal to 100 fs and less than or equal to 10 ns can be output at high power; thus, a large area can be processed at a time, and a time required for the deposition can be shortened. Thus, productivity can be improved. The use of the laser light having a very small pulse width as described above allows efficient thermal conversion in a light absorbing layer, and a material can be heated efficiently.

A light absorbing layer which converts laser light into heat is preferably provided between the second substrate and the material layer. As the light absorbing layer, a metal nitride, for example, titanium nitride or tungsten nitride is used. In addition, as the second substrate, a hard substrate having a high light-transmitting property, for example, a glass substrate or a quartz substrate is used. The light absorbing layer is formed into a desired island shape or a line shape, and is selectively provided. By evaporating the material layer which overlaps with the light absorbing layer, deposition can be selectively performed on the first substrate. The light absorbing layer can be formed on a glass substrate by a photolithography method, and a more precise pattern can be formed compared to that formed by a method for manufacturing a conventional evaporation mask.

Furthermore, it is not necessary to move a substrate, and the laser light may be scanned with the deposition target substrate fixed. Another aspect of the present invention is a manufacturing apparatus having a load chamber, a common chamber connected to the load chamber, a plurality of treatment chambers connected to the common chamber, and a laser light source, wherein a chamber wall of the common chamber has a window, in a lower part thereof, through which laser light from the laser light source passes; the common chamber has a vacuum exhaust means, an alignment means for substrates, and a scanning means for irradiating a substrate with laser light from the laser light source in a parallel or perpendicular direction to one side of the substrate.

The present invention solves at least one of the above-mentioned problems.

In the case where the laser light is scanned with the deposition target substrate fixed, it is necessary that the size of the window provided for the chamber wall of the common chamber be larger than that of a window of the manufacturing apparatus in which the substrate is moved.

Further, the deposition by laser light irradiation is preferably performed in a reduced-pressure atmosphere. For example, it is preferable that the common chamber have a pressure of less than or equal to 5×10⁻³ Pa, preferably, less than or equal to 10⁻⁴ Pa and greater than or equal to 10⁻⁶ Pa. The deposition can be performed by a sputtering method by setting the pressure in the common chamber within the above range.

In each of the above structures, a means for forming an electrode may be provided for the common chamber. As a method for forming the electrode, a sputtering method, an electron beam evaporation method, or the like can be used. In the case where the electrode is formed by a sputtering method in the common chamber, the common chamber includes at least a plasma generation means, and further includes a sputtering target and a means for introducing a source gas. The deposition is performed by laser light irradiation on the first substrate on which the electrode is formed in advance, and the other electrode is formed by a sputtering method. By forming the electrode by a sputtering method, a light emitting diode can be manufactured in the common chamber with preferable work efficiency. By forming the electrode on an organic layer such as a light emitting layer in the common chamber without transferring the first substrate from the common chamber, time in which the organic layer is exposed can be shortened, and mixing of an impurity can be suppressed; thus, an excellent light emitting diode can be manufactured.

Furthermore, the common chamber may have a means for moving a sputtering target stored in another chamber connected to the common chamber. The means for moving the sputtering target into the common chamber is a transfer robot, a movement device utilizing a ball screw, or a transfer crane. In this case, after the light emitting layer or the like is deposited on the first substrate, the sputtering target can be moved to the common chamber before deposition by a sputtering method is performed. Note that in the case where the deposition target substrate is placed with a face-up system in the deposition by a sputtering method, a mechanism for inverting the substrate is provided for the manufacturing apparatus.

Moreover, a light emitting device having light emitting diodes arranged in matrix can employ passive matrix drive (simple matrix type) or active matrix drive (active matrix type). The present invention can be applied to a light emitting device employing either driving method.

A light emitting diode can be manufactured in the common chamber with preferable work efficiency. The positional accuracy of selective deposition can be enhanced, and the distance between pixels having different emission colors can be designed to be short. Further, the material use efficiency can be improved in forming an organic thin film and manufacturing a light emitting device.

### BRIEF DESCRIPTION OF THE DRAWINGS

FIG. 1 is a schematic top view of a manufacturing apparatus;

FIG. 2 is a schematic perspective view when laser light is scanned;

FIGS. 3A to 3C are schematic cross-sectional views when laser light is scanned;

FIGS. 4A and 4B are a top view and a cross-sectional view illustrating a structure of a light emitting device; and

FIGS. 5A to 5E are diagrams illustrating examples of electronic appliances.

### DETAILED DESCRIPTION OF THE INVENTION

### Embodiment Mode

Embodiment mode of the present invention is described below.

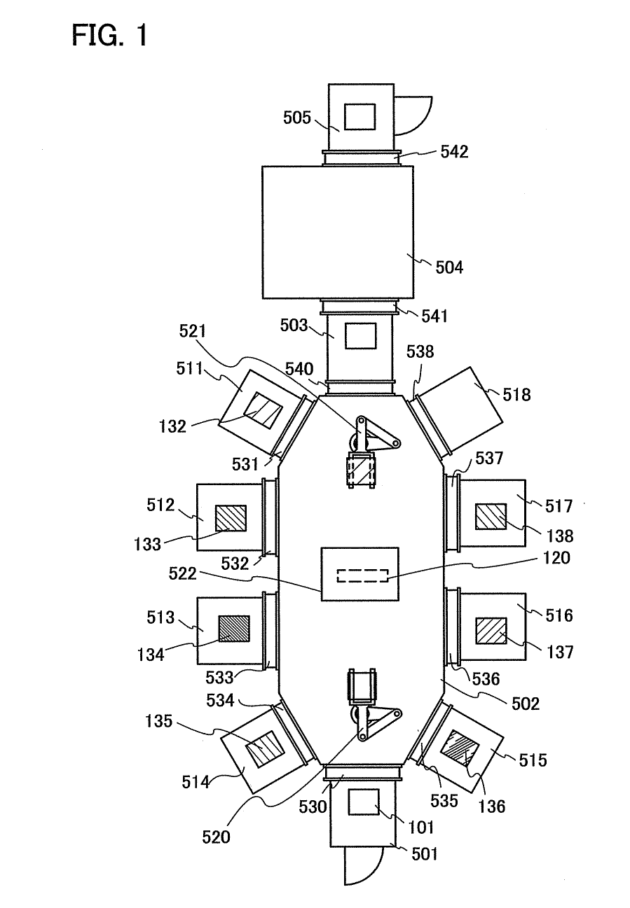

FIG. 1 is a schematic top view illustrating an example of a manufacturing apparatus.

The manufacturing apparatus illustrated in FIG. 1 includes a load chamber 501, a common chamber 502 connected to the load chamber 501, and a plurality of treatment chambers 511 to 518 connected to the common chamber. The treatment chambers are connected to the common chamber 502 through gate valves 531 to 538.

Since the manufacturing apparatus illustrated in FIG. 1 has a structure in which deposition is performed on a deposition target substrate in the common chamber 502, the common chamber 502 is preferably evacuated by providing a vacuum exhaust means to perform vacuum evacuation so that moisture or the like is not mixed. Further, as a material for an inner wall of the common chamber 502, aluminum, stainless steel (SUS), or the like which has been electropolished to have a mirror surface is used because the degree of adsorption of an impurity such as oxygen or moisture can be reduced by reducing the surface area of the inner wall. Accordingly, the degrees of vacuum of 10⁻⁴ Pa to 10⁻⁶ Pa can be maintained in the common chamber 502. Further, a material such as ceramics which has been processed so that there are quite few air holes is used as an inner member. Note that such a material preferably has surface smoothness where the centerline average roughness is less than or equal to 3 nm.

Further, the common chamber 502 is connected to an inert gas introduction system for introducing an inert gas (such as nitrogen) so that pressure in the common chamber is atmospheric pressure for maintenance of the common chamber 502.

In addition, the common chamber 502 has a window in a lower part thereof to introduce the laser light emitted from a laser light source into the common chamber.

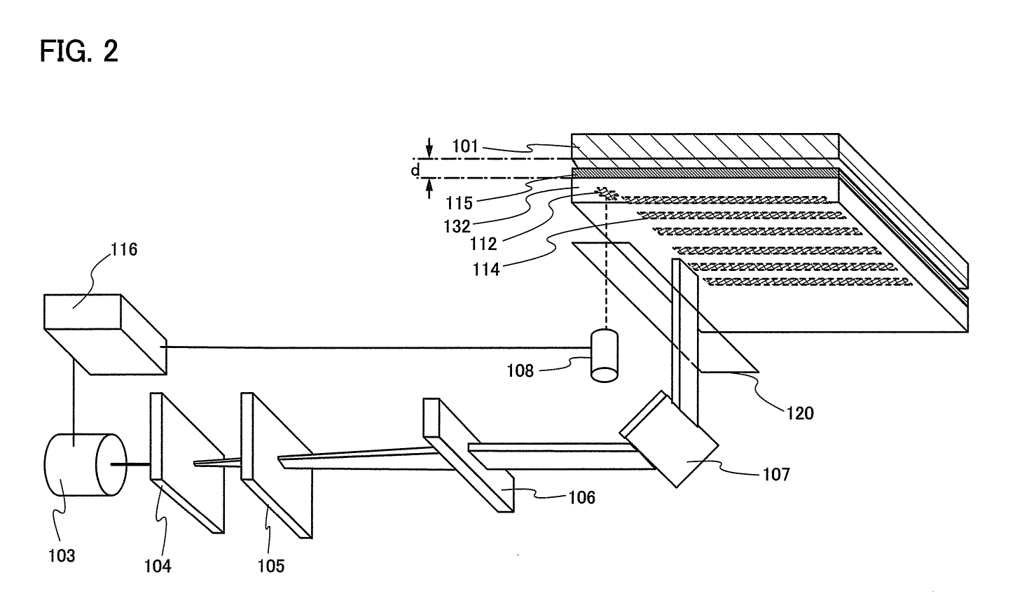

Here, a positional relationship between the window 120 and a laser oscillation device 103 is schematically illustrated in FIG. 2.

First, a deposition target substrate that is a first substrate 101 is transferred from the load chamber 501 to the common chamber 502 through a gate valve 530, and placed so that a deposition target surface of the first substrate 101 faces downward. In the load chamber, a plurality of first substrates 101 is set in a substrate cassette or the like so that the deposition target surfaces face downward to prevent adhesion of dust. The first substrate 101 is preferably vacuum-baked in advance; therefore, a vacuum bake mechanism is included in the load chamber. The vacuum bake chamber for removing moisture or the like attaching on the first substrate is preferably set between the load chamber 501 and the common chamber 502.

In addition, a second substrate 132 having a light absorbing layer 114 and a first material layer 115 which have selectively been provided in advance is placed so as to face the first substrate 101, keeping a distance d therebetween. For the light absorbing layer 114, a heat-resistant metal is preferably used, and for example, a single layer or a stacked layer formed using titanium, tungsten, tantalum, molybdenum, or the like is used. Here, titanium nitride that is metal nitride is used. FIG. 2 illustrates an example that the light absorbing layer 114 has a line pattern; however, the shape of the light absorbing layer 114 is not particularly limited, and may have a dot shape or have the same shape as that of a first electrode provided on the first substrate. Further, an example of providing the second substrate 132 with the first material layer 115 and the light absorbing layer 114 is illustrated; however, the present invention is not limited thereto, and a heat insulating layer or a reflective layer may be provided selectively. Note that the second substrate 132 is disposed so that a surface on which the first material layer is provided turns upward to face the deposition target surface of the first substrate 101. Positional alignment (alignment) of the first substrate 101 and the second substrate 132 is performed with an alignment means, and the first substrate 101 and the second substrate 132 are held with a certain distance d of at least less than or equal to 5 mm. The alignment means has at least an image pickup device and a control device for moving a substrate. In this specification, the distance d between a pair of substrates is a distance between two substrate planes that face each other, and is not a distance between structural objects provided on the substrate surfaces, such as the first electrode or the material layer provided on the substrate surface.

A plurality of first electrodes is provided for the first substrate 101; however, in the case where insulators that is partition walls for electrical isolation between the first electrodes is provided, the insulators and the material layer 115 may be in contact with each other.

Moreover, the pair of substrates is moved to be scanned with laser light with a certain distance d retained. At that time, the pair of substrates is moved in a long side or short side direction of a rectangular window by a substrate moving means 522. With the use of the substrate moving means 522, the pair of substrates can be moved at up to 1 m/sec. Here, an example of scanning laser light by moving the substrates is illustrated; however, it is not particularly limited; scanning may be performed by moving laser light with the substrates fixed. The substrate moving means 522 is also interlocked with a part of the above-mentioned alignment means, that is, also with the control device for moving the substrates.

The second substrate 132 is provided with a position marker 112 formed using the same material as that of the light absorbing layer 114, and a standard position of scanning is recognized by an image pickup device 108 for recognizing the position marker 112. It is preferable to have a device structure in which a field of view of the image pickup device 108 such as CCD is not interrupted. Because the second substrate is recognized from a lower side thereof, the second substrate 132 may be irradiated with an illumination light for a supplementary role. An example is illustrated in which the image pickup device 108 recognizes the position marker 112 through the window 120; however, it is not limited thereto, and a window may be separately provided or an image pickup device may be provided inside the chamber.

Laser light to be emitted is output from a laser oscillator 103; the laser light passes through a first optical system 104 for forming a laser beam into a rectangular laser beam, a second optical system 105 for shaping the laser beam, and a third optical system 106 for collimating the laser beam; and an optical path is changed into a direction perpendicular to the second substrate 132 by use of a reflecting mirror 107. After that, the laser beam passes through the window 120 which transmits light and the second substrate 132, so that the light absorbing layer 114 is irradiated with the laser beam. The window 120 can also function as a slit by having the same size as the width of the laser beam or a smaller size than the width of the laser beam.

The laser oscillator 103 emits laser light with a repetition rate of greater than or equal to 10 MHz and a pulse width of greater than or equal to 100 fs and less than or equal to 10 ns. With the use of the laser light with a repetition rate of greater than or equal to 10 MHz and a pulse width of greater than or equal to 100 fs and less than or equal to 10 ns, laser irradiation can be performed for a short time without optical interference; therefore, thermal diffusion can be controlled; the region of a second material layer which overlaps with the light absorbing layer 114 before laser irradiation can have about the same size as that of the region of a film deposited on the first substrate which has been subjected to laser irradiation; and formation of a thin film on the periphery of the deposition pattern, which leads to a larger deposition pattern than what a practitioner desires, can be reduced. When a thin film is formed on the periphery of the deposition pattern, the outline of the deposition pattern becomes vague; it can be said that laser light with a pulse width of greater than or equal to 100 fs and less than or equal to 10 ns can reduce the vague outline of the deposition pattern. The wavelength of the laser light is not particularly limited, and laser light having various wavelengths can be used. For example, laser light having a wavelength of 355 nm, 515 nm, 532 nm, 1030 nm, 1064 nm, or the like can be used. As the laser light, one or more of the following lasers can be used: a gas laser such as an Ar laser, a Kr laser, or an excimer laser; and a solid-state laser such as a laser whose medium is single-crystal YAG, YVO₄, forsterite (Mg₂SiO₄), YAlO₃, or GdVO₄ to which one or more of Nd, Yb, Cr, Ti, Ho, Er, Tm, and Ta has been added as a dopant or a polycrystalline (ceramic) YAG, Y₂O₃, YVO₄, YAlO₃, or GdVO₄ to which one or more of Nd, Yb, Cr, Ti, Ho, Er, Tm, and Ta has been added as a dopant, a glass laser, a ruby laser, an alexandrite laser, a Ti:sapphire laser; or a fiber laser. Alternatively, a second harmonic or a third harmonic oscillated from the above-described solid-state laser, or further, other higher harmonics can be used. Note that, when a solid-state laser whose laser medium is solid is used, there are advantages in that a maintenance-free condition can be maintained for a long time and output is relatively stable.

The spot of the laser preferably has a linear shape or a rectangular shape. By making the spot of the laser a linear shape or a rectangular shape, a treatment substrate can be efficiently scanned with laser light. Thus, time required for the deposition (take time) is shortened, and productivity is improved.

A control device 116 preferably controls a substrate moving means 522 which moves the pair of substrates. In addition, the control device 116 preferably controls the laser oscillator 103. Moreover, the control device 116 preferably controls a position alignment mechanism which has the image pickup device 108 for recognizing the position marker 112.

When scanning of the laser light is completed, the first material layer 115 which overlaps with the light absorbing layer 114 have disappeared from the second substrate 132, and deposition on the first substrate 101 that is placed to face the second substrate 132 has been performed selectively. Note that the first material layer 115 which does not overlap with the light absorbing layer 114 remains on the second substrate 132. If remaining material layers are removed from the second substrate 132 which has been scanned with laser light, the second substrate 132 can be used again

Next, a process for stacking layers is described with reference to FIG. 1. For example, in the case where a layer obtained on the first electrode of the first substrate by heating the first material layer provided over the second substrate is a hole injecting layer, after the hole injecting layer is selectively formed on the first substrate 101 by scanning the laser light according to the above procedure, a third substrate 133 on which the second material layer is formed in advance and the first substrate 101 are aligned and kept with a certain distance therebetween. This alignment is performed using the same apparatus as that used for the alignment of the second substrate and the first substrate. Because the same apparatus for alignment is used, position misalignment can be suppressed.

The treatment chamber 511 connected to the common chamber 502 is a deposition treatment chamber for depositing the first material layer on the second substrate. Further, the treatment chamber 512 connected to the common chamber 502 is a deposition treatment chamber for depositing the second material layer on the third substrate 133. The third substrate 133 is also provided with a light absorbing layer between the second material layer and the substrate surface. A layer obtained at a position which overlaps with the hole injecting layer of the first substrate by heating the second material layer provided over the third substrate 133 is a hole transporting layer.

Note that the common chamber 502 is provided with carrier units 520 and 521 such as a transfer robot arm, and transferring between the common chamber and each treatment chamber is performed with the use of the carrier units which transfer the first substrate, the second substrate, and the like.

The third substrate 133 and the first substrate 101 are aligned, and then scanned with laser light; thus, the hole transporting layer is stacked at a position which overlaps with the hole injecting layer of the first substrate. Note that a second material layer which does not overlap with the light absorbing layer remains on the third substrate 133. If remaining second material layers are removed from the third substrate 133 which has been scanned with laser light, the third substrate 133 can be used again

Through the above-described process, the layers can be stacked. In the case where the period of time from the end of deposition of the hole injecting layer to the start of deposition of the hole transporting layer is shortened, a place to temporarily set the second substrate which has been scanned with laser light, for example, a substrate cassette, is provided in the common chamber, thus, time when the hole transporting layer is exposed can be shortened. The second substrate and the third substrate are transferred to the common chamber almost simultaneously; a first laser light scanning is performed; the second substrate which has been scanned with laser light is moved to the substrate cassette; the third substrate which has already been transferred into the chamber is aligned with the first substrate, and the second laser light scanning is performed. In that case, because a gate valve of the common chamber is not opened and closed during the deposition treatment of the two layers, the degree of vacuum in the common chamber can be maintained, and contamination with an impurity can be prevented.

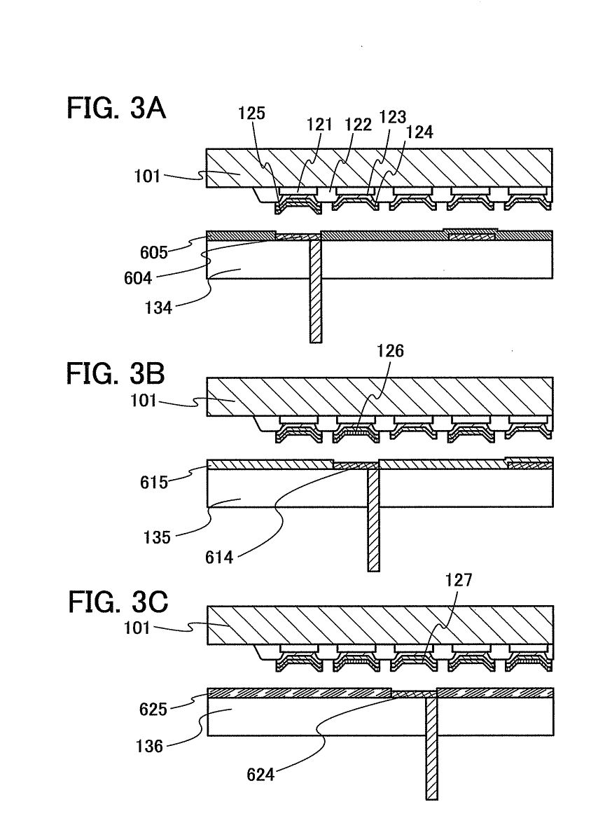

Furthermore, in order to manufacture a full-color light emitting device, a red light emitting layer, a green light emitting layer, and a blue light emitting layer are selectively deposited at intervals. This process is described with reference to FIGS. 3A to 3C.

Through the above steps, the laser light scanning is performed twice using the second substrate 132 and the third substrate 133; therefore, a hole injecting layer 123 and a hole transporting layer 124 are stacked over a first electrode 121 provided for the first substrate 101. Note that a partition wall 122 which covers an end portion of the first electrode 121 and insulates the adjacent first electrodes is provided for the first electrode 101.

The first substrate 101 and a fourth substrate 134 are aligned; the fourth substrate 134 and the first substrate 101 are placed to face each other; and a third laser scanning is performed with a certain distance between the substrates retained. FIG. 3A corresponds to a cross-sectional view in the middle of the third laser scanning.

A light absorbing layer 604 which is selectively formed and a third material layer 605 are formed over the fourth substrate 134 in advance. The third material layer 605 is deposited over the fourth substrate 134 in the treatment chamber 513, and the fourth substrate 134 is transferred to the common chamber.

As illustrated in FIG. 3A, by laser light irradiation, the third material layer 605 is partly heated, and a red light emitting layer 125 is selectively formed at a position which overlaps with the hole transporting layer 124.

Subsequently, the fourth substrate 134 which has been scanned with laser light is moved, and the first substrate 101 and a fifth substrate 135 are aligned with each other so that the fifth substrate 135 can face the first substrate 101. Then, a fourth laser scanning is performed with a certain distance between the substrates retained. FIG. 3B corresponds to a cross-sectional view in the middle of the fourth laser scanning.

A light absorbing layer 614 which is selectively formed and a fourth material layer 615 are formed over the fifth substrate 135 in advance. The fourth material layer 615 is deposited over the fifth substrate 135 in the treatment chamber 514, and the fifth substrate 135 is transferred to the common chamber.

As illustrated in FIG. 3B, by laser light irradiation, the fourth material layer 615 is partly heated, and a green light emitting layer 126 is selectively formed at a position which overlaps with the hole transporting layer 124.

Subsequently, the fifth substrate 135 which has been scanned with laser light is moved, and the first substrate 101 and a sixth substrate 136 are aligned with each other so that the sixth substrate 136 can face the first substrate 101. Then, a fifth laser scanning is performed with a certain distance between the substrates retained. FIG. 3C corresponds to a cross-sectional view in the middle of the fifth laser scanning.

A light absorbing layer 624 which is selectively formed and a fifth material layer 625 are formed over the sixth substrate 136 in advance. The fifth material layer 625 is deposited on the sixth substrate 136 in the treatment chamber 515, and the sixth substrate 136 is transferred to the common chamber.

As illustrated in FIG. 3C, by laser light irradiation, the fifth material layer 625 is partly heated, and a blue light emitting layer 127 is selectively formed at a position which overlaps with the hole transporting layer 124.

Through the above process, the red light emitting layer, the green light emitting layer, and the blue light emitting layer can be selectively deposited at intervals.

In the case where the period of time from the end of deposition of a light emitting layer to the start of the next deposition of a light emitting layer is shortened, a place to temporarily set the fourth substrate, the fifth substrate, and the sixth substrate which have been scanned with laser light, for example, a substrate cassette, is provided in the common chamber, thus, a period of time when each light emitting layer is exposed can be shortened. The fourth substrate, the fifth substrate, and the sixth substrate are transferred to the common chamber almost simultaneously; the third laser light scanning is performed; the fourth substrate which has been scanned with laser light is moved to the substrate cassette; the fifth substrate which has already been transferred into the chamber is aligned with the first substrate, and the fourth laser light scanning is performed. Moreover, the fifth substrate which has been scanned with laser light is moved to the substrate cassette; and the sixth substrate which has already been transferred into the chamber is aligned with the first substrate, and the fifth laser scanning is performed. In that case, because a gate valve of the common chamber is not opened and closed during the deposition treatment of the three layers, the degree of vacuum in the common chamber can be maintained, and contamination with an impurity can be prevented.

After that, a sixth laser scanning is performed using a seventh substrate 137 over which a sixth material layer is formed, thereby selectively forming an electron transporting layer which overlaps with each light emitting layer. The sixth material layer is deposited over the seventh substrate 137 in a treatment chamber 516 and the seventh substrate 137 is transferred to the common chamber.

Further, a seventh laser scanning is performed using an eighth substrate 138 over which a seventh material layer is formed, thereby selectively forming an electron injecting layer which overlaps with the electron transporting layer. The seventh material layer is deposited over the eighth substrate 138 in a treatment chamber 517 and the eighth substrate 138 is transferred to the common chamber.

In the case where the period of time from the end of deposition of the electron transporting layer to the start of the next deposition of the electron injecting layer is shortened, a place to temporarily set the seventh substrate 137 and the eighth substrate 138 which have been scanned with the laser light, for example, a substrate cassette, is to be provided in the common chamber; thus, the period of time when each light emitting layer is exposed can be shortened.

In a deposition method for heating a material layer which has been deposited in advance over a substrate that is different from a deposition target substrate with laser light, a necessary amount of a material for the deposition is limited, and the amount of the material evaporated is suppressed compared to that in a conventional resistance heating; thus, a plurality of transfer robots, alignment means, substrate moving mechanisms, and the like can be provided in the common chamber for performing deposition. Furthermore, in the deposition method for heating a material layer which has been deposited in advance over a substrate that is different from a deposition target substrate with laser light, even if different light emitting layers are deposited in the same treatment chamber, different light emitting materials are prevented from being mixed.

In addition, if a place to temporarily set the second to eighth substrates, for example, a substrate cassette, is provided, the second to eighth substrates can be transferred to the common chamber almost simultaneously when the first substrate is transferred to the common chamber. Provision of the same number of substrates as the number of layers to be deposited enables deposition in a short period of time.

Then, by forming a second electrode on the first substrate on which the aforementioned layers have been stacked, a light emitting diode having at least the first electrode, the second electrode, and the light emitting layer therebetween is manufactured. Note that the second electrode is formed by a sputtering method, an electron beam method, or the like. It is preferable that the second electrode be also formed in the common chamber, and in the case where a sputtering method is used, the common chamber is further provided with a plasma generation means, and a sputtering target and a means for introducing a source gas are provided. A shutter mechanism for preventing deposition on the window 120 in forming the second electrode is preferably provided.

In addition, a sputtering target may be stocked in the treatment chamber 518, and the sputtering target may be moved to the common chamber before forming the second electrode so that deposition can be performed by sputtering in the common chamber. In that case, a means for moving the sputtering target to the common chamber is provided.

After forming the second electrode, the first substrate is transferred to a delivery chamber 503 through a gate valve 540 using the carrier unit 521 and further carried into a sealing chamber 504 through a gate valve 541. The substrate that has been sealed in the sealing chamber 504 is transferred to an unload chamber 505 through a gate valve 542 and can be taken out of the manufacturing apparatus. Through the above-described process, a light emitting diode (also referred to as an EL element) can be manufactured.

Here, an example is illustrated in which an EL layer provided between the first electrode and the second electrode has five layers including a stack of the hole injecting layer, the hole transporting layer, the light emitting layer, the electron transporting layer, and the electron injecting layer; however, it is not limited hereto, and the EL layer may includes a stack of a hole transporting layer, a light emitting layer, and an electron transporting layer. A practitioner can appropriately design the structure in consideration of a light emitting material, luminous efficiency, and the like.

Furthermore, the treatment chamber 518 may be a stock chamber for stocking substrates which have been subjected to laser light irradiation. It is preferable that the treatment chamber 518 be a stock chamber for stocking substrates which have been subjected to laser light irradiation, and the first substrate on which the second electrode is formed be transferred to the delivery chamber 503 and the substrates which have been subjected to the laser light irradiation be transferred from the common chamber 502 to the treatment chamber 518 at the same time. Thus, next deposition on the first substrate which is transferred to the common chamber can be performed smoothly.

Moreover, the treatment chamber 518 may be a stock chamber for stocking the second to eighth substrates before laser light irradiation.

An example of forming the second electrode in the common chamber is illustrated in the aforementioned process; however, the treatment chamber 518 may be a deposition treatment chamber for forming the second electrode.

Although FIG. 1 illustrates only two carrier units are included in the common chamber; however, there is no particular limitation, and one of more carrier units may be further provided to efficiently transfer the second to eighth substrates. Furthermore, a carrier unit may be provided in the treatment chambers 511 to 518.

Furthermore, FIG. 1 illustrates a manufacturing apparatus in which a substrate is taken into the load chamber 501 and transferred out of the unload chamber 505; however, there is no particular limitation. The load chamber may be provided for each the treatment chamber 511 to 517 with a gate valve interposed therebetween. A substrate (the second to eighth substrates) provided with a light absorbing layer may be transferred from the load chamber provided for each the treatment chamber.

In the case where a material layer is formed in each of the treatment chambers 511 to 517 by a coating method (also referred to as a wet method) such as a spin coating method or a cast method, a bake chamber for baking is preferably provided between the common chamber and the treatment chamber. The use of the spin coating method leads to preferable work efficiency because a material layer is formed with a face-up system and a substrate can be transferred to the common chamber without being reversed and aligned with the first substrate.

In the case where a material layer is deposited in each of the treatment chamber 511 to 517 with a face-down system by an evaporation method or the like, a reverse mechanism is preferably provided for the carrier unit; alternatively, the treatment chamber 518 may be provided with a substrate reverse unit so as to serve as a reverse chamber.

### Embodiment 1

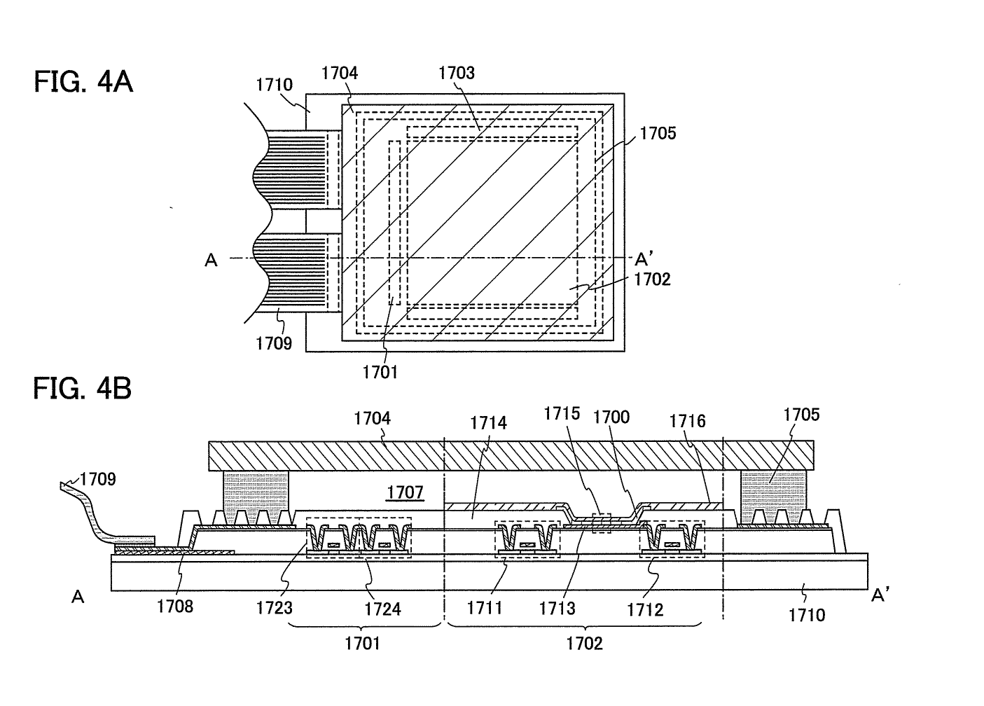

In this embodiment, an active matrix light emitting device formed with the use of the manufacturing apparatus shown in FIG. 1 will be described with reference to FIGS. 4A and 4B. FIG. 4A is a top view illustrating a light emitting device, and FIG. 4B is a cross-sectional view taken along the line A-A′ of FIG. 4A. A reference numeral 1701 indicated by a dotted line denotes a driver circuit portion (source side driver circuit); 1702 denotes a pixel portion; 1703 denotes a driver circuit portion (gate side driver circuit); 1704 denotes a sealing substrate; 1705 denotes a sealant, and 1707 denotes a space surrounded by the sealant 1705.

A reference numeral 1708 denotes a wiring for transmitting a signal input to the source side driver circuit 1701 and the gate side driver circuit 1703, and the wiring 1708 receives a video signal, a clock signal, a start signal, a reset signal, and the like from a flexible printed circuit (FPC) 1709 that is to be an external input terminal. Although only the FPC is illustrated here, a printed wiring board (PWB) may be attached to the FPC. The light emitting device in the present specification includes, in its category, not only the light emitting device itself but also the light emitting device provided with the FPC or the PWB.

Next, a cross-sectional structure will be described with reference to FIG. 4B. Although a driver circuit portion and a pixel portion are formed over an element substrate 1710, a pixel portion 1702 and a source side driver circuit 1701 that is a driver circuit portion are illustrated here.

As the source side driver circuit 1701, a CMOS circuit in which an n-channel TFT 1723 and a p-channel TFT 1724 are combined is formed. A circuit included in the driver circuit may be a known CMOS circuit, PMOS circuit, or NMOS circuit. In this embodiment, a driver-integrated type in which a driver circuit is formed over the same substrate is described; however, it is not necessary to have such a structure, and the driver circuit can be formed not over the substrate but outside the substrate.

The pixel portion 1702 is formed of a plurality of pixels each including a switching TFT 1711, a current control TFT 1712, and an anode 1713 that is electrically connected to a drain of the current control TFT 1712. An insulator 1714 is formed so as to cover an end portion of the anode 1713. Here, the insulator 1714 is formed using a positive type photosensitive acrylic resin film.

The insulator 1714 is formed so as to have a curved surface having curvature at an upper and lower end portions thereof in order to obtain favorable coverage. For example, when a positive type photosensitive acrylic is used as a material for the insulator 1714, a curved surface having a radius of curvature (0.2 to 3 μm) is preferably formed at the upper end portion of the insulator 1714. For the insulator 1714, either a negative type that becomes insoluble in an etchant by photosensitive light or a positive type that becomes soluble in an etchant by light can be used, and an inorganic compound such as silicon oxide or silicon oxynitride can be used as well as an organic compound.

An organic compound-containing stacked layer 1700 and a cathode 1716 are formed over the anode 1713. Here, the organic compound-containing stacked layer 1700 may have a structure in which a first anode, a hole injecting layer, a hole transporting layer, a light emitting layer, an electron transporting layer, an electron injecting layer, a second cathode, and the like are stacked as appropriate. Further, as a material used for the anode 1713, a material having a high work function is preferably used. For example, the following structures can be given: a stacked film of a titanium nitride film and a film containing aluminum as its main component; a stacked film having a three-layer structure of a titanium nitride film, a film containing aluminum as its main component, and a titanium nitride film; and the like as well as a single-layer film of an indium tin oxide film, an indium tin oxide film containing silicon, an indium zinc oxide film, a titanium nitride film, a chromium film, a tungsten film, a zinc film, a platinum film, or the like. In the case where the anode 1713 is formed of an indium tin oxide film and a wiring of the current control TFT 1712 connected to the anode 1713 has a stacked structure of a titanium nitride film and a film containing aluminum as its main component or a stacked structure of a titanium nitride film, a film containing aluminum as its main component, and a titanium nitride film, resistance of the wiring is low, a favorable ohmic contact with the indium tin oxide film can be formed. The anode 1713 may be formed using the same material as the first anode in the organic compound-containing stacked layer 1700. Alternatively, the anode 1713 may be stacked in contact with the first anode in the organic compound-containing stacked layer 1700.

The light emitting element 1715 has a structure in which the anode 1713, the organic compound-containing stacked layer 1700, and the cathode 1716 are stacked; specifically, a hole injecting layer, a hole transporting layer, a light emitting layer, an electron transporting layer, an electron injecting layer, and the like are stacked as appropriate. The light emitting layer 1715 may be formed by the deposition method in which a material layer which has been deposited in advance over a substrate that is different from a deposition target substrate is heated with laser light.

A material (Al, Ag, Li, Ca, or an alloy thereof: MgAg, MgIn, AlLi, calcium fluoride, or calcium nitride) having a low work function may be used as a material for the cathode 1716; however, the material for the cathode 1716 is not limited to the above and can employ a variety of conductive layers by selection of an appropriate electron injecting material. When light emitted from the light emitting element 1715 is made to be transmitted through the cathode 1716, for the cathode 1716, it is possible to use a stacked layer of a metal thin film with a reduced film thickness and a transparent conductive film of an indium oxide-tin oxide alloy, an indium oxide-zinc oxide alloy, zinc oxide, or the like. The cathode 1716 may be formed using the same material as the second cathode in the organic compound-containing stacked layer 1700. Alternatively, the cathode 1716 may be stacked in contact with the second cathode in the organic compound-containing stacked layer 1700.

Furthermore, the sealing substrate 1704 and the element substrate 1710 are attached to each other with the sealant 1705, whereby the light emitting element 1715 is provided in a space 1707 surrounded by the element substrate 1710, the sealing substrate 1704, and the sealant 1705. Note that the space 1707 may be filled with the sealant 1705 as well as an inert gas (e.g., nitrogen or argon).

Note that an epoxy resin is preferably used as the sealant 1705. In addition, such a material is preferably a material which does not transmit moisture or oxygen as much as possible. As a material used for the sealing substrate 1704, a plastic substrate made of FRP (fiberglass-reinforced plastics), PVF (polyvinyl fluoride), polyester, acrylic, or the like can be used as well as a glass substrate or a quartz substrate.

As described above, the light emitting device including the light emitting element can be obtained with the use of the manufacturing apparatus of the present invention. A manufacturing cost per substrate tends to be high because of TFT manufacturing; however, the manufacturing apparatus of the present invention illustrated in FIG. 1 that is a manufacturing apparatus in which a film-thickness monitor is not used makes it possible to drastically reduce deposition process time per substrate and realize drastic reduction in cost per light emitting device. In addition, by the use of the manufacturing apparatus illustrated in FIG. 1, material use efficiency can be increased as compared to the conventional manufacturing apparatus, and thus reduction in manufacturing cost can be realized.

Furthermore, if necessary, a chromaticity conversion film such as a color filter may be used in the light emitting device described in this embodiment.

As an active layer of a TFT which is placed in the pixel portion 1702, the following can be used as appropriate: an amorphous semiconductor film, a semiconductor film including a crystalline structure, a compound semiconductor film including an amorphous structure, or the like. In addition, as the active layer of the TFT, a semi-amorphous semiconductor film (also referred to as a microcrystalline semiconductor film) including a crystalline region, which is a semiconductor having an intermediate structure between an amorphous structure and a crystalline structure (including a single crystal structure and a polycrystalline structure), and a third condition that is stable in terms of free energy. A crystal grain of 0.5 to 20 nm is contained in at least part of the semi-amorphous semiconductor film. The raman spectrum is shifted to a lower wavenumber side than 520 cm⁻¹. The diffraction peaks of (111) and (220) that are thought to be derived from a Si crystal lattice are observed by X-ray diffraction. In addition, the semi-amorphous semiconductor film contains hydrogen or halogen of at least greater than or equal to 1 atomic % to terminate dangling bonds. The semi-amorphous semiconductor film is formed by glow discharge decomposition (plasma CVD) of a source gas such as SiH₄ as well as Si₂H₆, SiH₂Cl₂, SiHCl₃, SiCl₄, SiF₄, or the like. The above-described source gas may be diluted with H₂, or H₂ and one or more rare gas elements selected from He, Ar, Kr, and Ne. A dilution ratio may be in the range of 2 to 1000 times, pressure may be in the range of 0.1 Pa to 133 Pa, a power supply frequency may be 1 MHz to 120 MHz preferably 13 MHz to 60 MHz, and a substrate heating temperature may be less than or equal to 300° C., preferably 100° C. to 250° C. The concentration of an atmospheric constituent impurity such as oxygen, nitrogen, or carbon, as an impurity element in the film, is preferably less than or equal to 1×10²⁰ cm⁻¹; in particular, the concentration of oxygen is less than or equal to 5×10¹⁹/cm³, preferably less than or equal to 1×10¹⁹/cm³. The electron field-effect mobility μ of a TFT in which the semi-amorphous semiconductor film is used as the active layer is 1 to 10 cm²/Vsec.

Moreover, although an example of manufacturing an active matrix display device is described in this embodiment, a passive matrix display device can also be manufactured using the manufacturing apparatus illustrated in Embodiment Mode. In the passive matrix display device, conventionally, an EL layer is formed selectively by forming a partition wall as a stacked layer, making the partition wall a complex shape, for example, a reverse tapered shape so as to perform evaporation over the entire surface of the partition wall, and separating an evaporation film with the partition wall. However, by using the manufacturing apparatus illustrated in FIG. 1, an EL layer can be selectively formed without making the partition wall a complex shape, thus, the manufacturing apparatus illustrated in FIG. 1 is highly useful.

### Embodiment 2

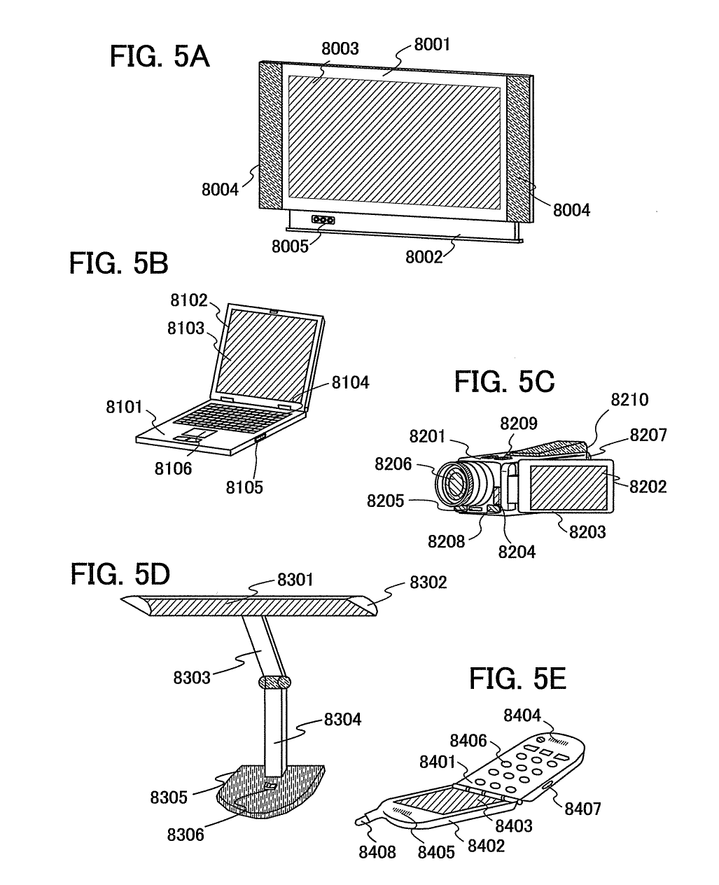

In this embodiment, with reference to FIGS. 5A to 5E, a variety of electronic appliances which are completed by use of a light emitting device which has a light emitting element manufactured by application of the manufacturing apparatus of the present invention will be described.

As electronic appliances which are manufactured with the use of the manufacturing apparatus of the present invention, the following can be given: televisions, cameras such as video cameras or digital cameras, goggle type displays (head mount displays), navigation systems, audio reproducing devices (e.g., car audio component stereos and audio component stereos), laptop personal computers, game machines, portable information terminals (e.g., mobile computers, cellular phones, portable game machines, and electronic books), and image reproducing devices provided with recording media (specifically, the devices that can reproduce a recording medium such as a digital versatile disc (DVD) and is provided with a display device capable of displaying the reproduced images), lighting equipment, and the like. Specific examples of these electronic appliances are shown in FIGS. 5A to 5E.

FIG. 5A shows a display device, which includes a chassis 8001, a supporting base 8002, a display portion 8003, speaker portions 8004, video input terminals 8005, and the like. The display device is manufactured using a light emitting device manufactured using the present invention for the display portion 8003. Note that the display device includes all devices for displaying information in its category, for example, devices for a personal computer, for receiving TV broadcasting, and for displaying an advertisement. The manufacturing apparatus of the present invention makes it possible to drastically reduce manufacturing cost and provide an inexpensive display device.

FIG. 5B shows a laptop personal computer, which includes a main body 8101, a chassis 8102, a display portion 8103, a keyboard 8104, an external connection port 8105, a pointing device 8106, and the like. A light emitting device which has a light emitting element formed with the use of the manufacturing apparatus of the present invention is used for the display portion 8103, and thus the laptop personal computer is manufactured. The manufacturing apparatus of the present invention makes it possible to drastically reduce manufacturing costs and provide an inexpensive laptop personal computer.

FIG. 5C shows a video camera, which includes a main body 8201, a display portion 8202, a chassis 8203, an external connection port 8204, a remote control receiving portion 8205, an image receiving portion 8206, a battery 8207, an audio input portion 8208, operation keys 8209, an eyepiece portion 8210, and the like. A light emitting device which has a light emitting element formed with the use of the manufacturing apparatus of the present invention is used for the display portion 8202, and thus the video camera is manufactured. The manufacturing apparatus of the present invention makes it possible to drastically reduce manufacturing cost and provide an inexpensive video camera.

FIG. 5D shows desk lighting equipment, which includes a lighting portion 8301, a shade 8302, an adjustable arm 8303, a support 8304, a base 8305, and a power supply 8306. A light emitting device manufactured with the use of the manufacturing apparatus of the present invention is used for the lighting portion 8301, and thus the desk lighting equipment is manufactured. Note that the lighting equipment includes a ceiling-fixed lighting equipment, a wall-hanging lighting equipment, and the like in its category. The manufacturing apparatus of the present invention makes it possible to drastically reduce manufacturing cost and provide inexpensive desk lighting equipment.

FIG. 5E shows a cellular phone, which includes a main body 8401, a chassis 8402, a display portion 8403, an audio input portion 8404, an audio output portion 8405, operation keys 8406, an external connection port 8407, an antenna 8408, and the like. A light emitting device which has a light emitting element with the use of the manufacturing apparatus of the present invention is used for the display portion 8403, and thus the cellular phone is manufactured. The manufacturing apparatus of the present invention makes it possible to drastically reduce manufacturing cost and provide an inexpensive cellular phone.

As described above, the electronic appliance or the lighting equipment using the light emitting element formed by use of the manufacturing apparatus of the present invention can be obtained. The application range of the light emitting device including the light emitting element formed by use of the manufacturing apparatus of the present invention is so wide that the light emitting device can be applied to electronic appliances in various fields.

The light emitting device described in this embodiment can be implemented in free combination with Embodiment Mode or Embodiment 1.

This application is based on Japanese Patent Application serial no. 2008-049691 filed with Japan Patent Office on Feb. 29, 2008, the entire contents of which are hereby incorporated by reference.

What is claimed is:

1. A manufacturing apparatus comprising:
a load chamber;
a common chamber connected to the load chamber;
a plurality of treatment chambers connected to the common chamber, wherein at least one of the plurality of treatment chambers includes a means for forming a material layer on a substrate; and
a laser light source,
wherein a chamber wall of the common chamber has a window through which laser light from the laser light source passes, and
wherein the common chamber includes:
a vacuum exhaust means,
an alignment means for the substrate, and
a transfer means for transferring the substrate between the common chamber and the one of the plurality of treatment chambers.

2. The manufacturing apparatus according to claim 1, wherein the laser light source emits the laser light at a repetition rate of greater than or equal to 10 MHz and with a pulse width of greater than or equal to 100 fs and less than or equal to 10 ns.

3. The manufacturing apparatus according to claim 1, wherein the common chamber further includes at least a plasma generation means, a sputtering target and a means for introducing a gas.

4. The manufacturing apparatus according to claim 3, wherein the common chamber further includes a means for moving a sputtering target.

5. A manufacturing apparatus comprising:
a load chamber;
a common chamber connected to the load chamber;
a plurality of treatment chambers connected to the common chamber; and
a laser light source,
wherein a chamber wall of the common chamber has a window, through which laser light from the laser light source passes,
wherein the common chamber includes:
a vacuum exhaust means,
an alignment means for a first substrate and a second substrate, and
a substrate moving means for moving the first substrate and the second substrate in a parallel or perpendicular direction to one side the window in a state of fixing both the first and second substrates,
wherein one of the plurality of treatment chambers includes a means for forming a material layer on the second substrate; and
wherein the alignment means align the first and second substrates so that a surface of the second substrate on which the material layer is formed faces a deposition target surface of the first substrate, and fixes the distance between the substrates.

6. The manufacturing apparatus according to claim 5, wherein the common chamber further includes a transfer means for transferring the second substrate on which the material layer is formed from the one of the plurality of treatment chambers.

7. The manufacturing apparatus according to claim 5, wherein an electrode or a thin film transistor is formed on one surface of the first substrate.

8. The manufacturing apparatus according to claim 5, wherein the surface of the second substrate on which the material layer is formed is selectively provided with a light absorbing layer which absorbs laser light between the surface of the second substrate and the material layer.

9. The manufacturing apparatus according to claim 5, wherein the laser light source emits the laser light at a repetition rate of greater than or equal to 10 MHz and with a pulse width of greater than or equal to 100 fs and less than or equal to 10 ns.

10. The manufacturing apparatus according to claim 5, wherein the common chamber further includes at least a plasma generation means, a sputtering target and a means for introducing a gas.

11. The manufacturing apparatus according to claim 10, wherein the common chamber further includes a means for moving a sputtering target.

12. A manufacturing apparatus comprising:
a load chamber;
a common chamber connected to the load chamber;
a plurality of treatment chambers connected to the common chamber, wherein a material layer is formed on a substrate in at least one of the plurality of treatment chambers; and
a laser light source,
wherein a chamber wall of the common chamber has a window through which laser light from the laser light source passes, and
wherein the material layer formed on the substrate is irradiated with the laser light in the common chamber.
